(19) United States
(12) Patent Application Publication
(10) Pub. No.: US 2025/0212654 A1
(43) Pub. Date: Jun. 26, 2025

(54) ENCAPSULATION STRUCTURE

(71) Applicant: INDUSTRIAL TECHNOLOGY RESEARCH INSTITUTE, Hsinchu (TW)

(72) Inventors: Jane-Hway LIAO, Hsinchu City (TW); Chun-Ting LIN, New Taipei City (TW); Keng-Hsien LIN, Tainan City (TW); Chien-Chang HUNG, Hsinchu City (TW); Yi-Hsiang HUANG, Changhua City (TW); Shu-Tang YEH, Hsinchu City (TW)

(73) Assignee: INDUSTRIAL TECHNOLOGY RESEARCH INSTITUTE, Hsinchu (TW)

(21) Appl. No.: 18/625,793

(22) Filed: Apr. 3, 2024

(30) Foreign Application Priority Data
Dec. 22, 2023 (TW) 112150217

(51) Int. Cl. H10K 59/80; G02B 6/35; H01L 25/16; H01L 33/54; H10K 77/10

(52) U.S. Cl. CPC H10K 59/873; G02B 6/3538; H01L 25/167; H10H 20/853; H10K 77/111

(57) ABSTRACT

An encapsulation structure is provided. The encapsulation structure includes a flexible substrate that has an element area and a non-element area. The encapsulation structure also includes multiple electronic elements disposed in the element area. The encapsulation structure further includes multiple light-guiding structures disposed on the electronic elements. The light-guiding structure includes a convex structure and/or a concave structure. The convex structure, in a cross-section, has at least one curved surface, at least two inclined surfaces, or a combination of at least one curved surface and one inclined surface. The concave structure, in a cross-section, has at least one curved surface or at least two inclined surfaces.

### CROSS REFERENCE TO RELATED APPLICATIONS

This application claims priority of Taiwan Patent Application No. 112150217, filed on Dec. 22, 2023, the entirety of which is incorporated by reference herein.

### TECHNICAL FIELD

The embodiments of the present disclosure relate to an encapsulation structure that includes multiple light-guiding structures.

### BACKGROUND

Thanks to technological advancements, electronic elements are now widely applied in various areas of life. Electronic elements have evolved from being rigid and inflexible towards being stretchable and/or flexible, thanks to changes in the materials used in their manufacture. For example, flexible substrates have replaced rigid substrates in many applications, and various parts of electronic elements have been developed that use flexible materials (e.g., organic materials).

However, when electronic elements serve as light-emitting elements (e.g., display panels, screens, and so on) and are fixed on non-flat surfaces (e.g., the A-pillar of a car) or are implemented in bendable electronic devices (e.g., stretchable displays), issues such as certain areas being exceptionally bright or dark may arise, leading to poor light uniformity and poor display quality.

### SUMMARY

An encapsulation structure is provided according to some embodiments of the present disclosure. The encapsulation structure includes a flexible substrate that has an element area and a non-element area. The encapsulation structure also includes multiple electronic elements disposed in the element area. The encapsulation structure further includes multiple light-guiding structures disposed on the electronic elements. Each light-guiding structure includes a convex and/or a concave structure. The convex structure, in a cross-section, has at least one curved surface, at least two inclined surfaces, or a combination of at least one curved surface and one inclined surface. The concave structure, in a cross-section, has at least one curved surface or at least two inclined surfaces.

An encapsulation structure is provided according to some other embodiments of the present disclosure. The encapsulation structure includes a flexible substrate that has an element area and a non-element area. The encapsulation structure also includes an electronic element disposed in the element area. The encapsulation structure further includes a deformable light-guiding structure disposed on the electronic element. Moreover, the encapsulation structure includes a shape-adjusting pad in direct or in indirect contact with the deformable light-guiding structure for changing the shape of the deformable light-guiding structure.

### BRIEF DESCRIPTION OF THE DRAWINGS

Aspects of the embodiments of the present disclosure can be understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a partial cross-sectional view illustrating an encapsulation structure according to some embodiments of the present disclosure.

FIG. 1B is a three dimensional view illustrating the light-guiding structure according to an embodiment.

FIG. 1C is a simulation diagram showing the brightness of the light-guiding structure observed from different positions.

FIG. 1D is a partial cross-sectional view illustrating the encapsulation structure according to other embodiments of the present disclosure.

FIG. 2A is a partial cross-sectional view illustrating the encapsulation structure according to an embodiment of the present disclosure.

FIG. 2B is a three dimensional view illustrating the light-guiding structure according to an embodiment.

FIG. 2C is a simulation diagram showing the brightness of the light-guiding structure observed from different positions in the encapsulation structure.

FIG. 3A is a partial cross-sectional view illustrating the encapsulation structure according to an embodiment of the present disclosure.

FIG. 3B is a three dimensional view illustrating the light-guiding structure according to an embodiment.

FIG. 3C is a simulation diagram showing the brightness of the light-guiding structure observed from different positions in the encapsulation structure.

FIG. 4A is a partial cross-sectional view illustrating the encapsulation structure according to an embodiment of the present disclosure.

FIG. 4B is a three dimensional view illustrating the light-guiding structure according to an embodiment.

FIG. 4C is a simulation diagram showing the brightness of the light-guiding structure observed from different positions in the encapsulation structure.

FIG. 5A is a partial cross-sectional view illustrating the encapsulation structure according to an embodiment of the present disclosure.

FIG. 5B is a three dimensional view illustrating the light-guiding structure according to an embodiment.

FIG. 5C is a simulation diagram showing the brightness of the light-guiding structure observed from different positions in the encapsulation structure.

FIG. 6A is a partial cross-sectional view illustrating the encapsulation structure according to an embodiment of the present disclosure.

FIG. 6B is a three dimensional view illustrating the light-guiding structure according to an embodiment.

FIG. 6C is a simulation diagram showing the brightness of the light-guiding structure observed from different positions in the encapsulation structure.

FIG. 7A is a partial cross-sectional view illustrating the encapsulation structure according to an embodiment of the present disclosure.

FIG. 7B is a three dimensional view illustrating the light-guiding structure according to an embodiment.

FIG. 7C is a simulation diagram showing the brightness of the light-guiding structure observed from different positions in the encapsulation structure.

FIG. 8A is a partial cross-sectional view illustrating the encapsulation structure according to an embodiment of the present disclosure.

FIG. 8B is a three dimensional view illustrating the light-guiding structure according to an embodiment.

FIG. 8C is a simulation diagram showing the brightness of the light-guiding structure observed from different positions in the encapsulation structure.

FIG. 9A is a partial cross-sectional view illustrating the encapsulation structure according to an embodiment of the present disclosure.

FIG. 9B is a three dimensional view illustrating the light-guiding structure according to an embodiment.

FIG. 9C is a simulation diagram showing the brightness of the light-guiding structure observed from different positions in the encapsulation structure.

FIG. 10A is a partial cross-sectional view illustrating the encapsulation structure according to an embodiment of the present disclosure.

FIG. 10B is a three dimensional view illustrating the light-guiding structure according to an embodiment.

FIG. 10C is a simulation diagram showing the brightness of the light-guiding structure observed from different positions in the encapsulation structure.

FIG. 11A to FIG. 11E are partial cross-sectional views illustrating encapsulation structures according to other embodiments of the present disclosure.

FIG. 12A and FIG. 12B are partial cross-sectional views illustrating changing the shape of the light-guiding structure through the encapsulation body (shape-adjusting pad) according to an embodiment of the present disclosure.

FIG. 13A to FIG. 13D are top views illustrating the encapsulation body and the light-guiding structure according to other embodiments of the present disclosure.

FIG. 14A is a partial cross-sectional schematic view illustrating the encapsulation body according to an embodiment of the present disclosure.

FIG. 14B illustrates a partial cross-sectional schematic view of changing the shape of the light-guiding structure through the encapsulation body (shape-adjusting pad) according to an embodiment of the present disclosure.

FIG. 15 is a schematic view of applying the encapsulation structure of the present disclosure to an object with a curved surface according to an embodiment of the present disclosure.

### DETAILED DESCRIPTION

The following disclosure provides many different embodiments, or examples, for implementing different features of the subject matter provided. Several examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

Furthermore, spatially relative terms, such as “beneath,” “below,” “lower,” “on,” “above,” “upper” and the like, may be used herein for ease of description to describe one element or feature's relationship to other elements or features as shown in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean+/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

The present disclosure may repeat reference numerals and/or letters in following embodiments. This repetition is for the purpose of simplicity and clarity and does not in itself dictate a relationship between the various embodiments and/or configurations discussed.

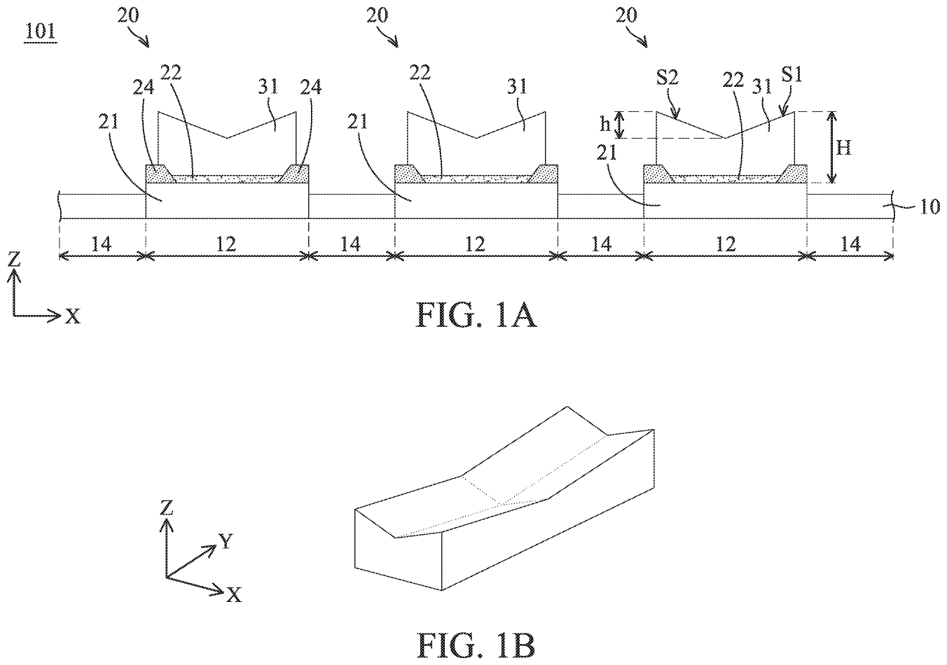

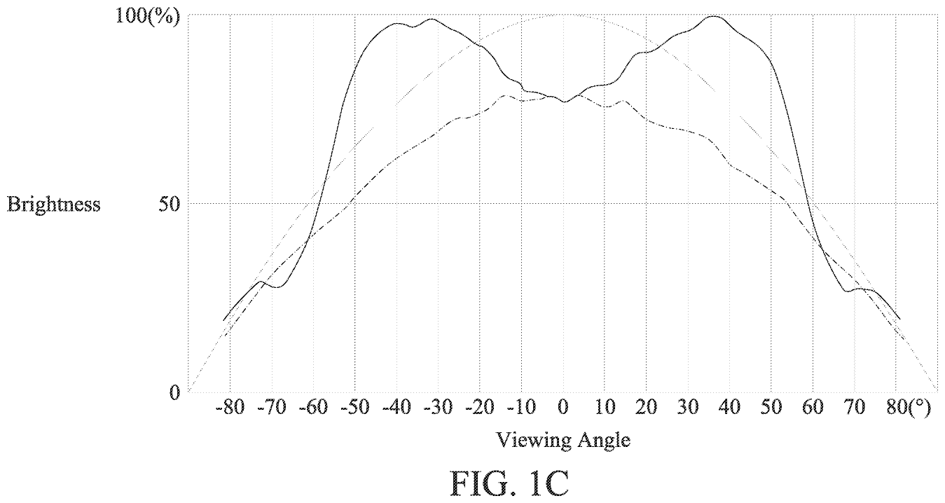

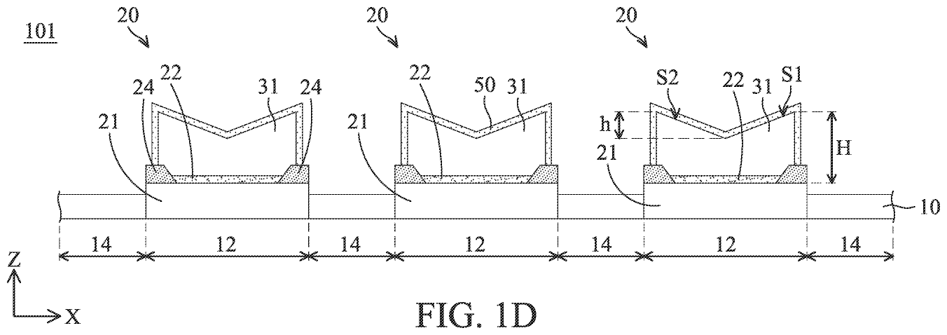

FIG. 1A is a partial cross-sectional view illustrating an encapsulation structure 101 according to some embodiments of the present disclosure. It should be noted that some components of the encapsulation structure 101 have been omitted in FIG. 1A for the sake of brevity.

Referring to FIG. 1A, in some embodiments, the encapsulation structure 101 includes a flexible substrate 10, which has an element area 12 and a non-element area 14. For example, the flexible substrate 10 may include polyimide (PI), silicone, polycarbonate (PC), ultra-thin glass, composite materials, or composite multi-layer stack materials (such as copper foil laminated plastic or the like), with a Young's modulus ranging from 0.1 GPa to 20 GPa, but the present disclosure is not limited thereto. Here, the flexible substrate 10 includes a substrate that may be flexed, bent, an elastic substrate that may be elastically stretched and recovered multiple times, or a one-time conformal deformation wrapping-typed substrate. Apart from material selection, different combinations of stretchable substrates may be achieved through methods such as multi-layer stacking/laminating, laser engraving, mechanical engraving, wet film processes (e.g., wet coating), or combinations thereof.

The element area 12 may be a flexible/bendable substrate, an elastic substrate, or a one-time deformation substrate, where the material's elongation is less than or equal to 15%, for example, including polyimide (PI), glass, or rigid plastics (e.g., acrylate, acrylonitrile butadiene styrene (ABS), Teflon, polyethylene terephthalate (PET), polycarbonate (PC), and so on); the non-element area 14 may use the same or different materials as the element area 12, with material's elongation greater than or equal to 5% (for example, up to 480%), such as polyimide (PI), polyurethane (PU), polyvinyl chloride (PVC), acrylonitrile butadiene styrene (ABS), polycarbonate (PC), silicone, and other materials.

Referring to FIG. 1A, in some embodiments, the encapsulation structure 101 also includes multiple electronic elements 20 disposed in the element area 12 of the flexible substrate 10. In this embodiment, electronic elements 20 may be arranged within the flexible substrate 10 using embedding, insetting, multi-layer lamination, etc., but the present disclosure is not limited thereto. Generally, the electronic elements 20 may include at least one active device (e.g., transistors, memory, or similar devices) and multiple passive devices (e.g., capacitors, resistors, inductors, similar devices, or combinations thereof). The flexible substrate 10 may have multiple interconnect structures (e.g., lines or vias), which are electrically connected to the electronic elements 20 in different element areas 12 to form functional circuits.

In some embodiments, the electronic elements 20 may be electroluminescent (EL) devices, quantum dot (QD) light emitters, organic light-emitting diodes (OLEDs), micro light-emitting diodes (micro LEDs), flexible hybrid electronics (FHE) components, or other suitable electronic elements, but the present disclosure is not limited thereto. In some embodiments, the electronic element 20 includes a control substrate 21 and a light-emitting structure 22 disposed on the control substrate 21. The control substrate 21 is connected to the flexible substrate 10 to control the light-emitting structure 22.

The control substrate 21 may be a substrate that includes functional components such as thin-film transistors (TFTs) or integrated circuits (ICs), or other types of circuit substrates. For example, the control substrate 21 may include elemental semiconductors (e.g., silicon or germanium), compound semiconductors (e.g., silicon carbide (SiC), gallium arsenide (GaAs), indium arsenide (InAs), or indium phosphide (InP)), alloy semiconductors (e.g., SiGe, SiGeC, GaAsP, or GaInP), other applicable semiconductors, or combinations thereof. Alternatively, the control substrate 21 may also be a semiconductor-on-insulator (SOI) substrate. The control substrate 21 may include various conductive components (e.g., conductive lines or vias). For example, the conductive components may include aluminum (Al), copper (Cu), tungsten (W), an alloy thereof, any other appropriate conductive material, or a combination thereof, but the present disclosure is not limited thereto.

The light-emitting structure 22 may emit red light, green light, or blue light, but the present disclosure is not limited thereto colors. The light-emitting structure 22 may also emit white light, cyan light, magenta light, yellow light, any other suitable color of light, or a combination thereof.

Referring to FIG. 1A, in some embodiments, the encapsulation structure 101 may further include multiple light-guiding structures 31 disposed on the electronic elements 20. In this embodiment, the light-guiding structures 31 may be a concave structure, and in the cross-section shown in FIG. 1A, the light-guiding structure 31 includes two inclined surfaces S1 and S2. In some embodiments, each light-guiding structure 31 may be designed to correspond to one or more pixel structures in the electronic elements 20 or to correspond to a sub-pixel structure as required.

FIG. 1B is a three dimensional view illustrating the light-guiding structure 31 according to an embodiment. FIG. 1C is a simulation diagram showing the brightness of the light-guiding structure 31 observed from different positions. In FIG. 1C, the horizontal axis represents different observation angles (i.e., viewing angle) (unit: degrees)) (°, the vertical axis represents the observed brightness (unit: %), the line segment X represents the distribution curve of light intensity and angle along the X-axis, the line segment Y represents the distribution curve of light intensity and angle along the Y-axis, and the line segment ref represents the distribution curve of light intensity and angle of an ideal light source (also known as a Lambertian-distribution light source).

As shown in FIG. 1B, the light-guiding structure 31 is a mid-recessed structure. That is, in this embodiment, the light-guiding structure 31 has two inclined surfaces in two mutually perpendicular cross-sections. The cross-section of the light-guiding structure 31 cut along the X-axis (i.e., the X-Z cross-section shown in FIG. 1A) includes two symmetrical inclined surfaces, and the cross-section of the light-guiding structure 31 cut along the Y-axis (the unillustrated Y-Z cross-section) also includes two symmetrical inclined surfaces. In other embodiments, the inclined surfaces may also be adjusted to an asymmetrical structure as required. The embodiments with inclined surfaces are also applicable.

In this embodiment, the light-emitting area of the light-guiding structure 31 is exemplified as approximately 12×45.75 μm², the light-guiding structure 33 has a refractive index of approximately 1.4, the maximum thickness H of the light-guiding structure 31 (see FIG. 1A) is about 8 μm, and the distance h between the highest point and the lowest point of the light-guiding structure 31 (see FIG. 1A) is about 0.8 μm. As shown in FIG. 1C, when the viewing angle ranges approximately from −25° to −60° or from +25° to +60°, the brightness of line segment X is higher compared to line segment Ref, indicating better display quality within this range for encapsulation structure 101.

As shown in FIG. 1A, in some embodiments, the encapsulation structure 101 may include multiple encapsulation bodies 24 surrounding the light-emitting structure 22. The encapsulation bodies 24 and the corresponding light-guiding structures 31 may be in direct contact. It should be noted that although each encapsulation body 24 in FIG. 1A surrounds a single light-emitting structure 22, the encapsulation body 24 may also surround a row or a column (e.g., 1×n or n×1, where n is a positive integer) of light-emitting structures 22. Alternatively, the encapsulation body 24 may surround an area (e.g., n×n) of light-emitting structures 22. For example, the encapsulation body 24 may surround a pixel area (e.g., including three sub-pixels) of light-emitting structures 22.

The encapsulation body 24 may be made of organic materials, inorganic materials, or stacks of organic and inorganic materials, which may include polysilazane, epoxy resin, phenolic resin, silicon oxide (SiOₓ), silicon nitride (SiNₓ), silicon oxynitride (SiOₓN_{y}), acrylic, polyurethane, any other suitable material, or a combination thereof. Moreover, the encapsulation body 24 may also serve as a barrier layer, such as a black matrix layer or a shape-adjusting pad (which may be used to adjust the shape of the light-guiding structure 31 above the encapsulation body 24). The encapsulation body 24 may be formed by a deposition process, a coating process, a plasma treatment, a heat treatment, a lamination, a casting, an etching process, any other suitable process, or a combination thereof. For example, the coating process may include spin coating, doctor blade coating, slot-die coating, dip coating, inkjet coating, screen printing. The deposition process may include chemical vapor deposition (CVD), physical vapor deposition (PVD), sputtering, but the present disclosure is not limited thereto.

FIG. 1D is a partial cross-sectional view illustrating the encapsulation structure 101 according to other embodiments of the present disclosure. Referring to FIG. 1D, in this embodiment, the encapsulation structure 101 further includes a barrier layer 50 covering the light-guiding structures 31. For example, the barrier layer 50 may include polysilazane, silicon oxynitride (SiOₓN_{y}), silicon oxide (SiOₓ), silicon nitride (SiNₓ), stacks of these materials, or similar. Moreover, the thickness of the barrier layer 50 may be less than about 1 μm, but the present disclosure is not limited thereto.

The barrier layer 50 may be formed by a coating process and a surface treatment, and so on. For example, the coating process may include methods similar to those mentioned earlier; the surface treatment may include light treatment, heat treatment, or plasma treatment, but the present disclosure is not limited thereto. The surface treatment may modify the surface of the barrier layer 50 to have higher density, thereby enhancing the barrier properties of the barrier layer 50.

In some embodiments, the surface of the barrier layer 50 treated with plasma may further include dopant elements. The dopant element may be a constituent element of the plasma gas, including, for example, argon, hydrogen, nitrogen, oxygen, any other inert gas, any other suitable gas, or a combination thereof. In some embodiments, the content of dopant elements in the barrier layer 50 may exceed 0 at % to about 5 at %, where at % is the atomic percentage. The barrier layer 50 may cover the surface of the light-guiding structure 31, reducing the ingress of water vapor and/or oxygen into the electronic elements 20 from the light-guiding structure 31.

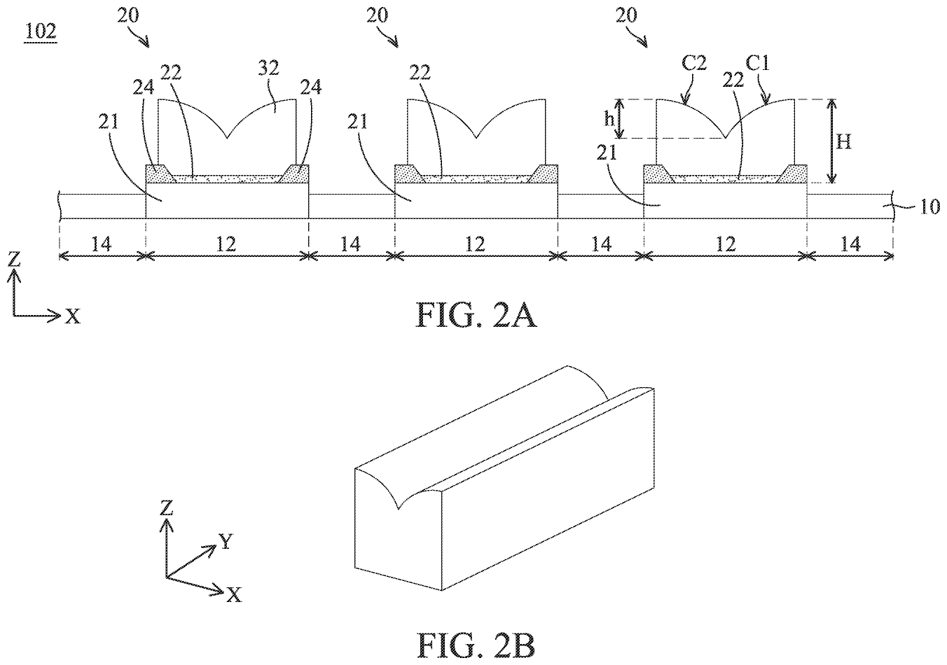

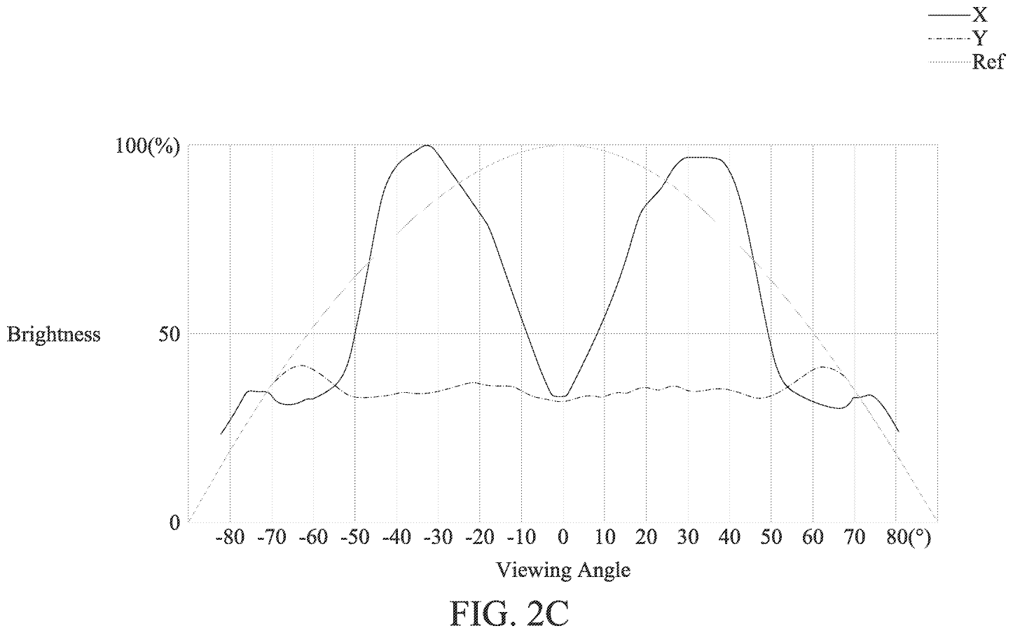

FIG. 2A is a partial cross-sectional view illustrating the encapsulation structure 102 according to an embodiment of the present disclosure. FIG. 2B is a three dimensional view illustrating the light-guiding structure 32 according to an embodiment. FIG. 2C is a simulation diagram showing the brightness of the light-guiding structure 32 observed from different positions in the encapsulation structure 102. Similarly, some components of the encapsulation structure 102 have been omitted in FIG. 2A for the sake of brevity.

Referring to FIG. 2A, in some embodiments, the encapsulation structure 102 includes a flexible substrate 10 that has an element area 12 and a non-element area 14. The encapsulation structure 102 also includes multiple electronic elements 20 disposed in the element area 12 of the flexible substrate 10. The encapsulation structure 102 may further include multiple light-guiding structures 32 disposed on the electronic elements 20. Moreover, the encapsulation structure 102 may include multiple encapsulation bodies 24 surrounding the light-emitting structure 22. Although not shown in FIG. 2A, in other embodiments, the encapsulation structure 102 may also include a barrier layer 50 covering the light-guiding structure 32, which will not be further elaborated here.

As shown in FIG. 2A and FIG. 2B, in this embodiment, the light-guiding structure 32 may be a concave structure, and in the cross-section shown in FIG. 2A, the light-guiding structure 32 has two curved surfaces C1 and C2. As shown in FIG. 2B, in this embodiment, the light-guiding structure 32 includes a groove that is formed by two curved surfaces (i.e., curved surfaces C1 and C2). The cross-section of the light-guiding structure 32 cut along the X-axis (i.e., the X-Z cross-section shown in FIG. 2A) includes two symmetrical curved surfaces. In other embodiments, the two curved surfaces may also be adjusted to an asymmetrical structure as required. The embodiments with curved surfaces are also applicable.

In this embodiment, the light-emitting area of the light-guiding structure 31 is exemplified as approximately 12×45.75 μm², the light-guiding structure 32 has a refractive index of approximately 1.4, the maximum thickness H of the light-guiding structure 32 (see FIG. 2A) is about 4.6 μm, and the distance h between the highest point and the recessed point of the light-guiding structure 32 (see FIG. 2A) is about 4.6 μm. As shown in FIG. 2C, when the viewing angle ranges approximately from −30° to −45° or from +30° to +45°, the brightness of line segment X is higher compared to line segment Ref. This indicates that within the ranges, the encapsulation structure 102 achieves better display quality.

In other embodiments, adjusting the refractive index of the light-guiding structure 32, for example, by changing the material or composition of the light-guiding structure 32, may improve the brightness of the encapsulation structure 102 across different viewing angles. For example, when the light-guiding structure 32 has a refractive index of approximately 1.35, sufficient brightness may be achieved within a viewing angle that ranges approximately from −20° to −45° or from +20° to +45°. Alternatively, when the light-guiding structure 32 has a refractive index of approximately 1.75, sufficient brightness may be achieved within a viewing angle that ranges approximately from −25° to −50° or from +25° to +50°. Thus, by adjusting the refractive index of the light-guiding structure 32, the visible range of the encapsulation structure 102 may be expanded.

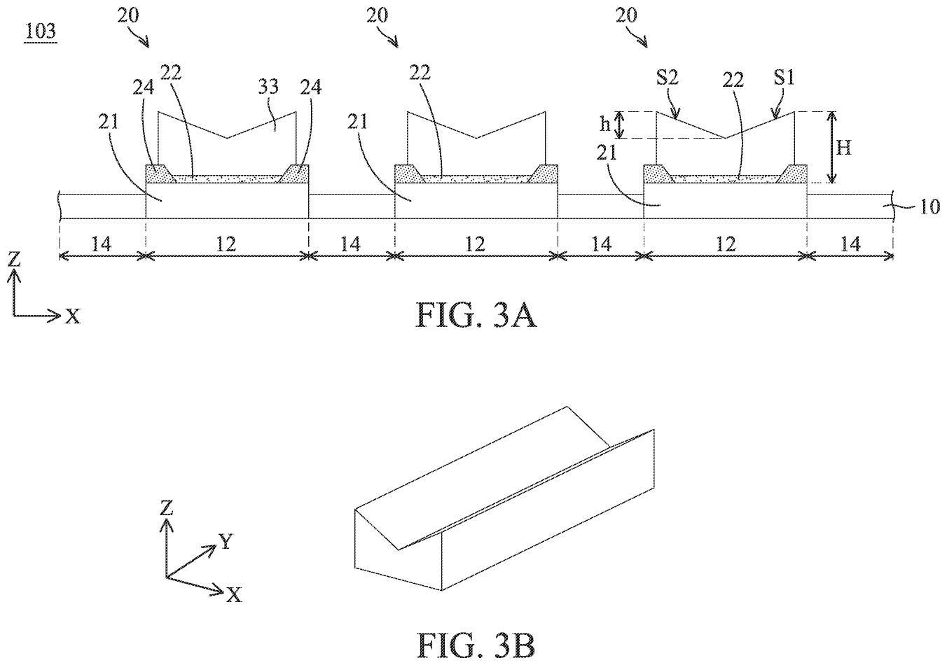

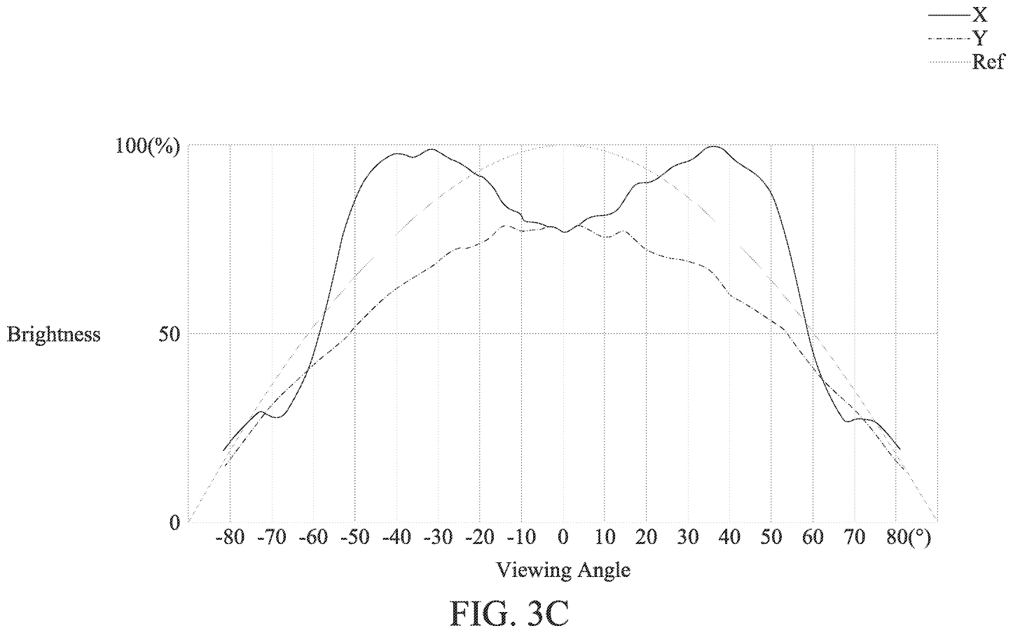

FIG. 3A is a partial cross-sectional view illustrating the encapsulation structure 103 according to an embodiment of the present disclosure. FIG. 3B is a three dimensional view illustrating the light-guiding structure 33 according to an embodiment. FIG. 3C is a simulation diagram showing the brightness of the light-guiding structure 33 observed from different positions in the encapsulation structure 103. Similarly, some components of the encapsulation structure 103 have been omitted in FIG. 3A for the sake of brevity. Although not shown in FIG. 3A, in other embodiments, the encapsulation structure 103 may also include a barrier layer 50 covering the light-guiding structure 33, which will not be further elaborated here.

As shown in FIG. 3A and FIG. 3B, in this embodiment, the light-guiding structure 33 is a concave structure, and in the cross-section shown in FIG. 3A, the light-guiding structure 33 includes two inclined surfaces S1 and S2. As shown in FIG. 3B, in this embodiment, the light-guiding structure 33 includes a groove formed by two inclined surfaces (i.e., inclined surfaces S1 and S2). The cross-section of the light-guiding structure 33 cut along the X-axis (i.e., the X-Z cross-section shown in FIG. 3A) includes two inclined surfaces.

In this embodiment, the light-guiding structure 33 has a refractive index of approximately 1.4, the maximum thickness H of the light-guiding structure 33 (see FIG. 3A) is about 8 μm, and the distance h between the highest point and the recessed point of the light-guiding structure 33 (see FIG. 3A) is about 3 μm. As shown in FIG. 3C, when the viewing angle ranges approximately from −25° to −55° or from +25° to +55°, the brightness of line segment X is higher compared to line segment Ref. This indicates that within the ranges, the encapsulation structure 103 achieves better display quality.

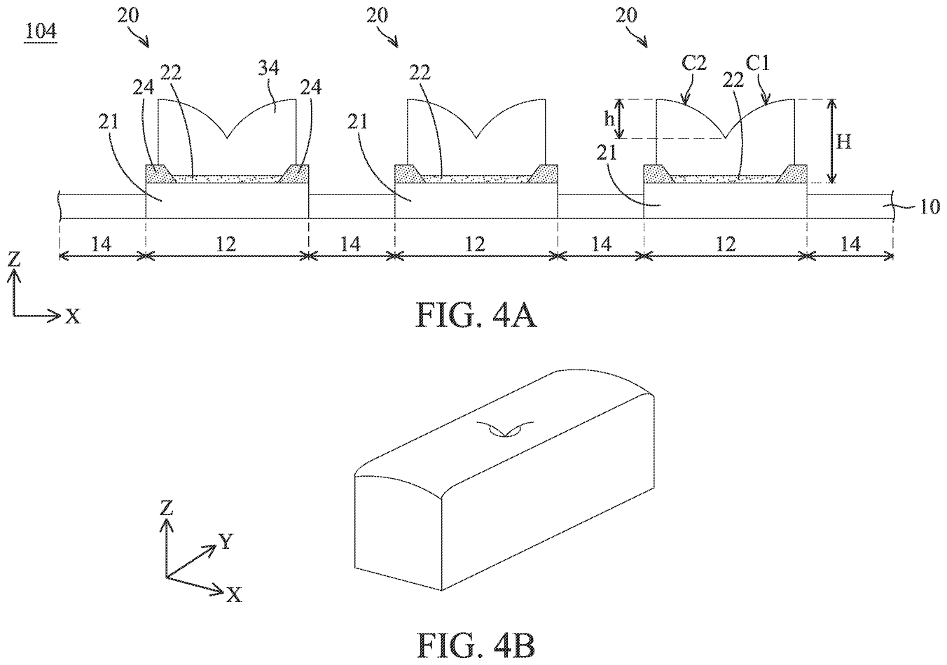

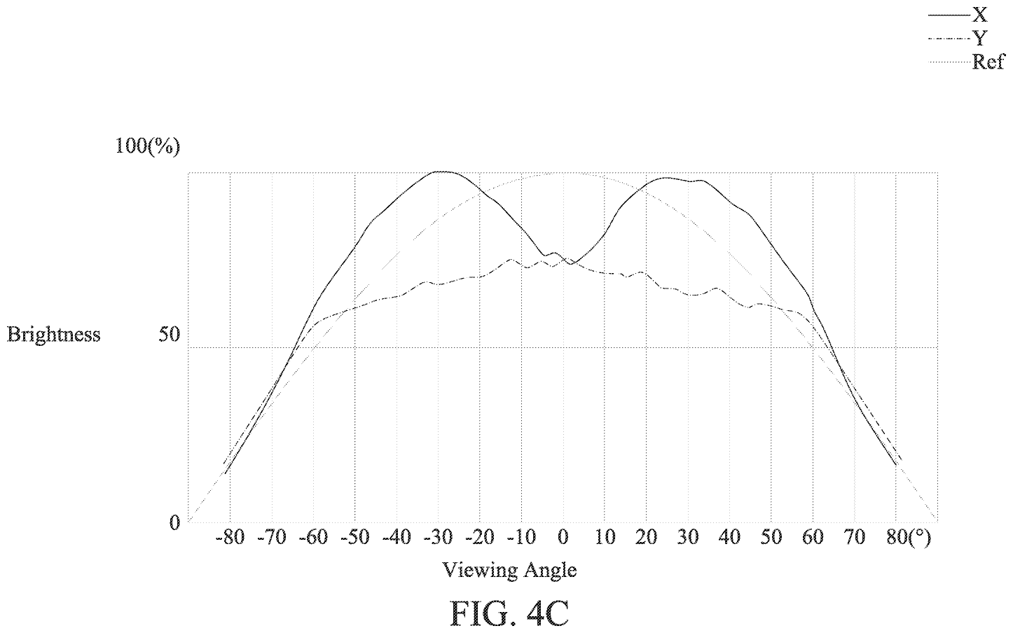

FIG. 4A is a partial cross-sectional view illustrating the encapsulation structure 104 according to an embodiment of the present disclosure. FIG. 4B is a three dimensional view illustrating the light-guiding structure 34 according to an embodiment. FIG. 4C is a simulation diagram showing the brightness of the light-guiding structure 34 observed from different positions in the encapsulation structure 104. Similarly, some components of the encapsulation structure 104 have been omitted in FIG. 4A for the sake of brevity. Although not shown in FIG. 4A, in other embodiments, the encapsulation structure 104 may also include a barrier layer 50 covering the light-guiding structure 34, which will not be further elaborated here.

As shown in FIG. 4A and FIG. 4B, in this embodiment, the light-guiding structure 34 may be a concave structure, and in the cross-section shown in FIG. 4A, the light-guiding structure 34 has two curved surfaces C1 and C2. As shown in FIG. 4B, in this embodiment, the light-guiding structure 34 is a mid-recessed structure. The cross-section of the light-guiding structure 34 cut along the X-axis (i.e., the X-Z cross-section shown in FIG. 4A) includes two curved surfaces, and the cross-section of the light-guiding structure 34 cut along the Y-axis (the unillustrated Y-Z cross-section) also includes two curved surfaces.

In this embodiment, the light-guiding structure 34 has a refractive index of approximately 1.4, the maximum thickness H of the light-guiding structure 34 (see FIG. 4A) is about 17.9 μm, and the distance h between the highest point and the recessed point of the light-guiding structure 34 (see FIG. 4A) is about 4.6 μm. As shown in FIG. 4C, when the viewing angle ranges approximately from −20° to −55° or from +20° to +55°, the brightness of line segment X is higher compared to line segment Ref. This indicates that within the ranges, the encapsulation structure 104 achieves better display quality.

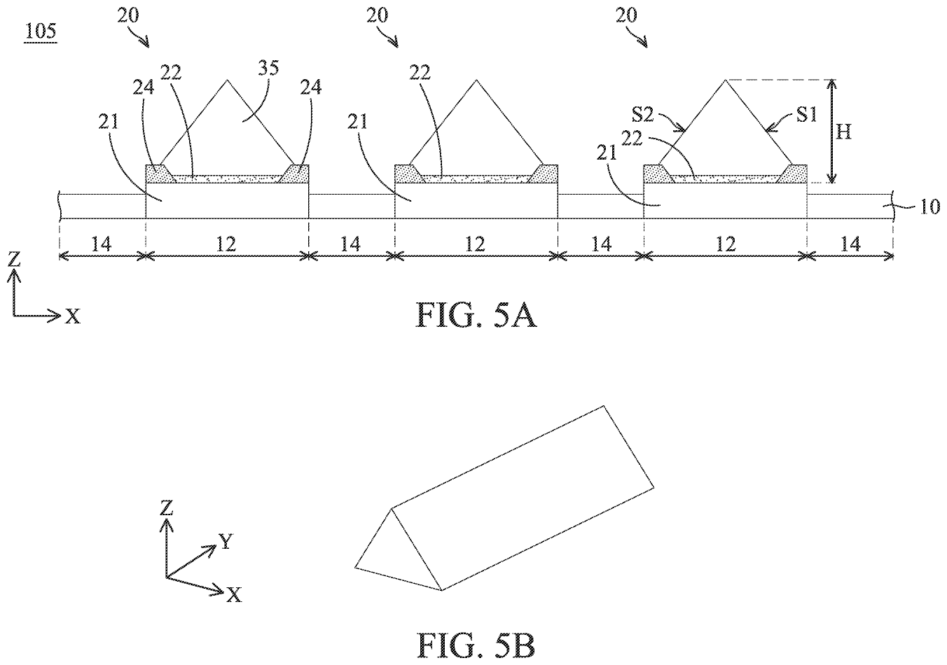

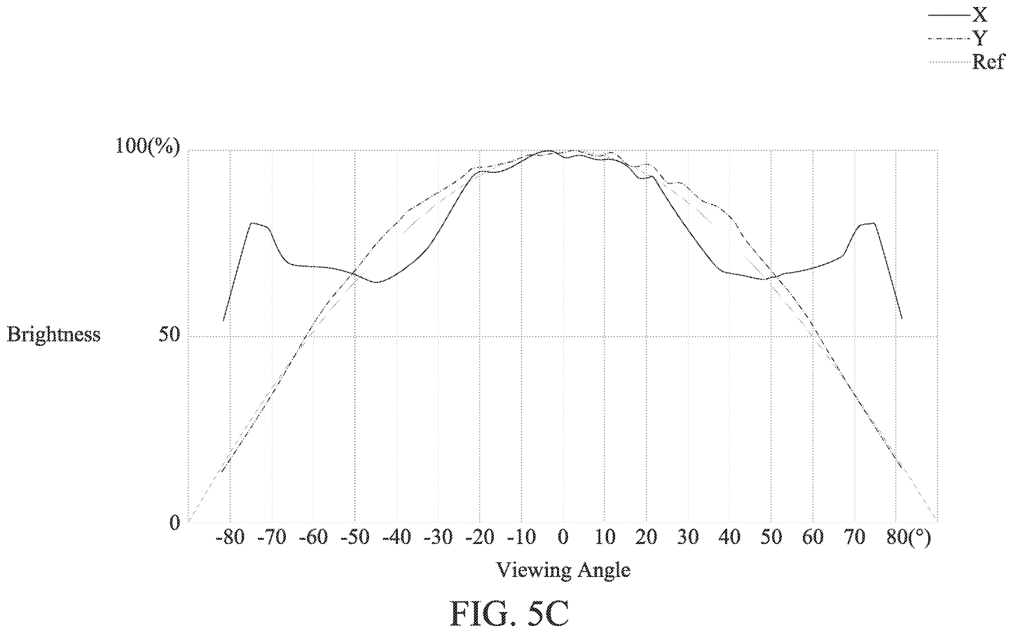

FIG. 5A is a partial cross-sectional view illustrating the encapsulation structure 105 according to an embodiment of the present disclosure. FIG. 5B is a three dimensional view illustrating the light-guiding structure 35 according to an embodiment. FIG. 5C is a simulation diagram showing the brightness of the light-guiding structure 35 observed from different positions in the encapsulation structure 105. Similarly, some components of the encapsulation structure 105 have been omitted in FIG. 5A for the sake of brevity. Although not shown in FIG. 5A, in other embodiments, the encapsulation structure 105 may also include a barrier layer 50 covering the light-guiding structure 35, which will not be further elaborated here.

As shown in FIG. 5A and FIG. 5B, in this embodiment, the light-guiding structure 35 is a convex structure, and in the cross-section shown in FIG. 5A, the light-guiding structure 35 includes two inclined surfaces S1 and S2. As shown in FIG. 5B, in this embodiment, the light-guiding structure 35 may be a triangular prism. The cross-section of the light-guiding structure 35 cut along the X-axis (i.e., the X-Z cross-section shown in FIG. 5A) includes two inclined surfaces.

In this embodiment, the light-guiding structure 35 has a refractive index of approximately 1.4, the maximum thickness H of the light-guiding structure 35 (see FIG. 5A) is about 10 μm. As shown in FIG. 5C, when the viewing angle ranges approximately from −60° to −75° or from +60° to +75°, the brightness of line segment X is higher compared to line segment Ref. That is, it has sufficient brightness when the viewing angle ranges approximately from −75° to +75°. This indicates that within the ranges, the encapsulation structure 105 achieves better display quality.

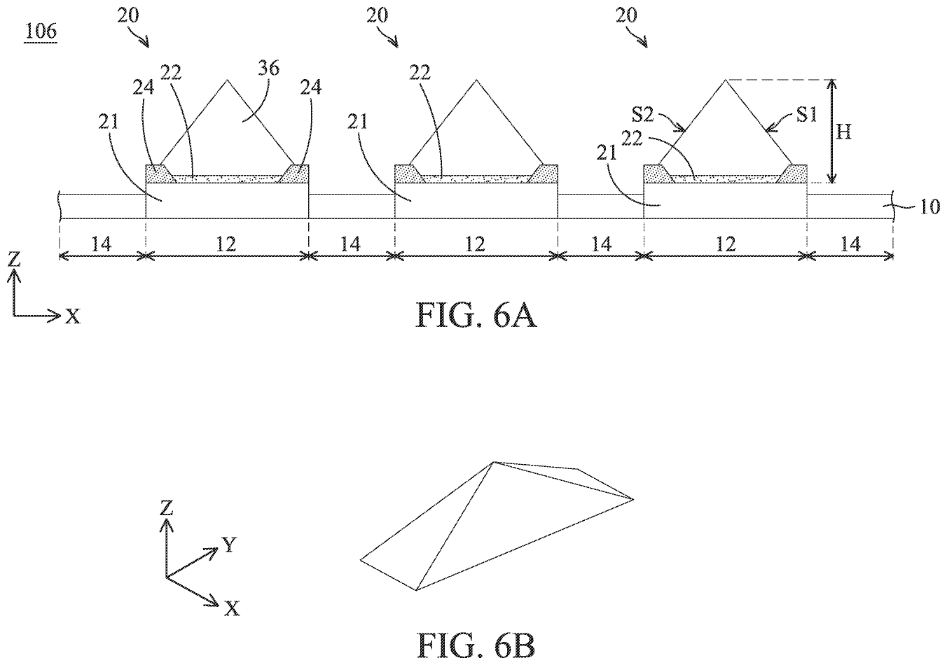

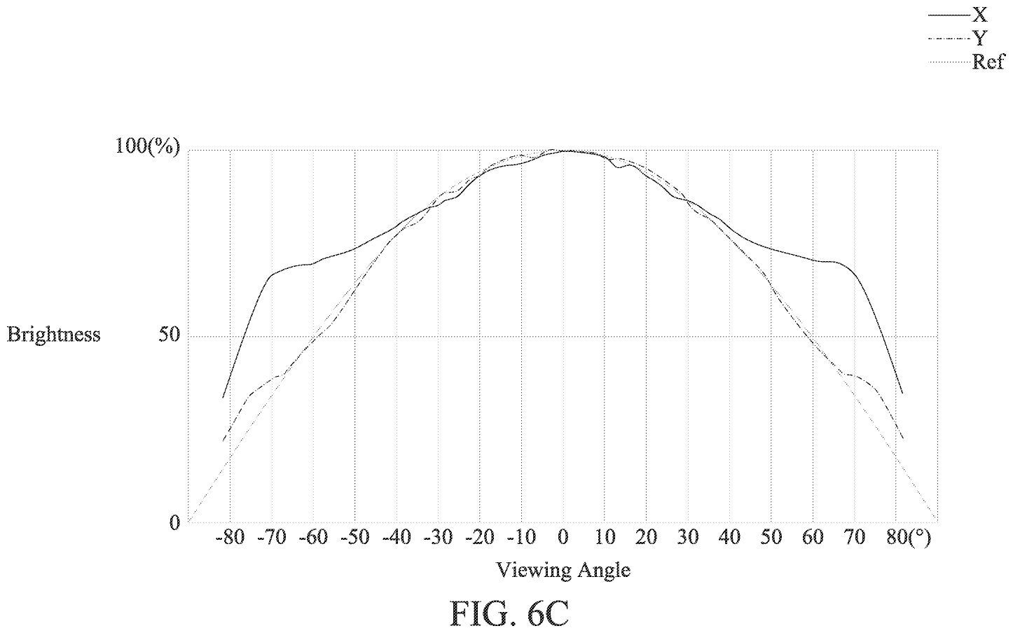

FIG. 6A is a partial cross-sectional view illustrating the encapsulation structure 106 according to an embodiment of the present disclosure. FIG. 6B is a three dimensional view illustrating the light-guiding structure 36 according to an embodiment. FIG. 6C is a simulation diagram showing the brightness of the light-guiding structure 36 observed from different positions in the encapsulation structure 106. Similarly, some components of the encapsulation structure 106 have been omitted in FIG. 6A for the sake of brevity. Although not shown in FIG. 6A, in other embodiments, the encapsulation structure 106 may also include a barrier layer 50 covering the light-guiding structure 36, which will not be further elaborated here.

As shown in FIG. 6A and FIG. 6B, in this embodiment, the light-guiding structure 36 is a convex structure, and in the cross-section shown in FIG. 6A, the light-guiding structure 36 includes two inclined surfaces S1 and S2. As shown in FIG. 6B, in this embodiment, the light-guiding structure 36 may be a quadrangular prism, or a pyramid. The cross-section of the light-guiding structure 36 cut along the X-axis (i.e., the X-Z cross-section shown in FIG. 6A) includes two inclined surfaces.

In this embodiment, the light-guiding structure 36 has a refractive index of approximately 1.4, the maximum thickness H of the light-guiding structure 36 (see FIG. 6A) is about 14 μm. As shown in FIG. 6C, when the viewing angle ranges approximately from −30° to −70° or from +30° to +70°, the brightness of line segment X is higher compared to line segment Ref. That is, it has sufficient brightness when the viewing angle ranges approximately from −70° to +70°. This indicates that within the ranges, the encapsulation structure 106 achieves better display quality.

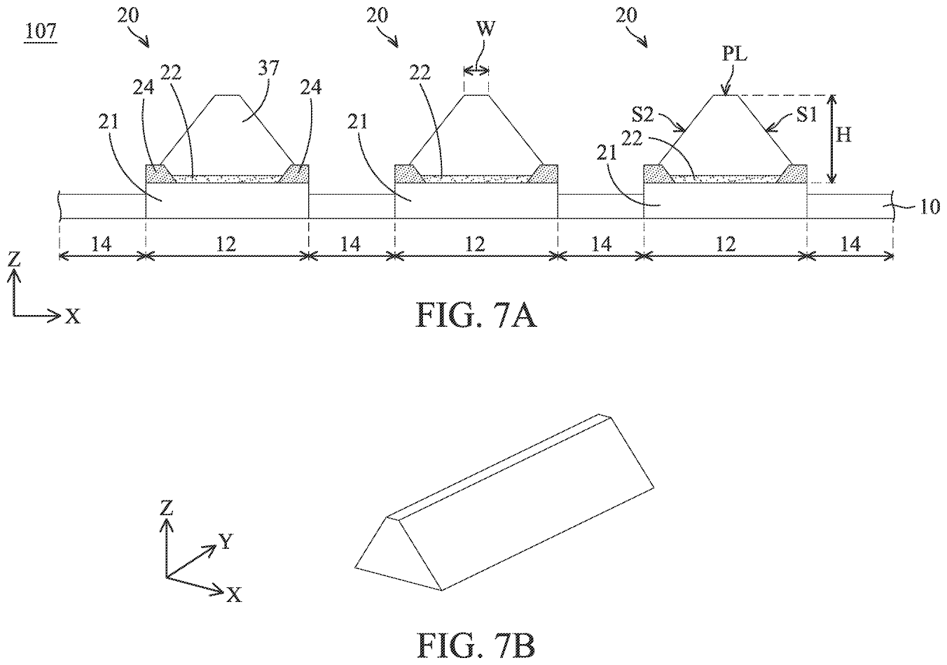

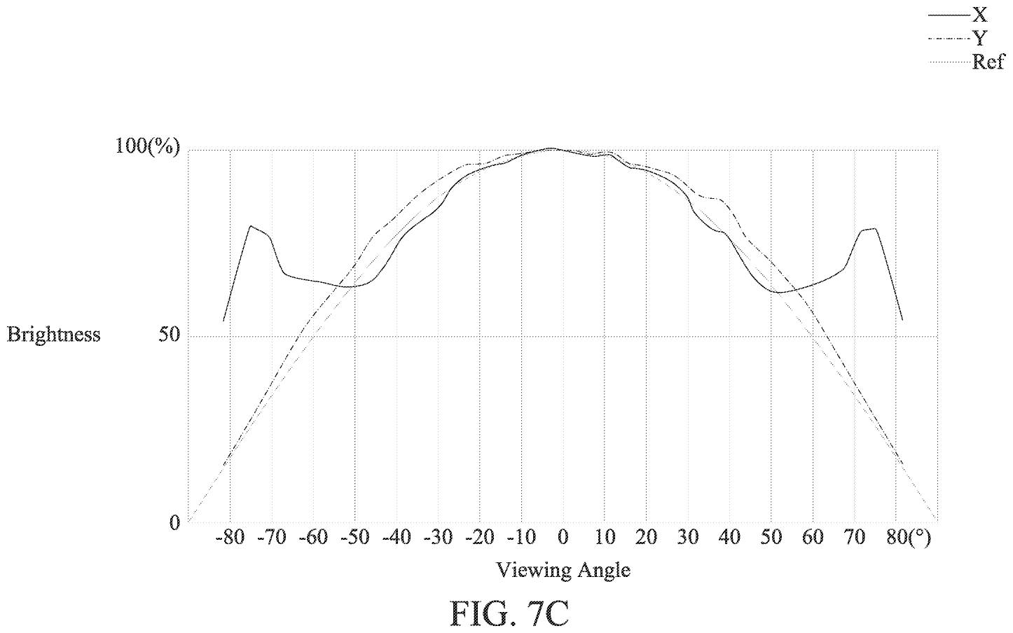

FIG. 7A is a partial cross-sectional view illustrating the encapsulation structure 107 according to an embodiment of the present disclosure. FIG. 7B is a three dimensional view illustrating the light-guiding structure 37 according to an embodiment. FIG. 7C is a simulation diagram showing the brightness of the light-guiding structure 37 observed from different positions in the encapsulation structure 107. Similarly, some components of the encapsulation structure 107 have been omitted in FIG. 7A for the sake of brevity. Although not shown in FIG. 7A, in other embodiments, the encapsulation structure 107 may also include a barrier layer 50 covering the light-guiding structure 37, which will not be further elaborated here.

As shown in FIG. 7A and FIG. 7B, in this embodiment, the light-guiding structure 37 is a convex structure, and in the cross-section shown in FIG. 7A, the light-guiding structure 37 includes two inclined surfaces S1 and S2. As shown in FIG. 7B, in this embodiment, the light-guiding structure 37 may be a quadrangular prism. The cross-section of the light-guiding structure 37 cut along the X-axis (i.e., the X-Z cross-section shown in FIG. 7A) is trapezoidal that includes two inclined surfaces.

In this embodiment, the light-guiding structure 37 has a refractive index of approximately 1.4, the maximum thickness H of the light-guiding structure 37 (see FIG. 7A) is about 10 μm, and the width W of the flat portion PL on the top of the light-guiding structure 37 (as seen in FIG. 7A) is about 4 μm. As shown in FIG. 7C, when the viewing angle ranges approximately from −55° to −75° or from +55° to +75°, the brightness of line segment X is higher compared to line segment Ref. That is, it has sufficient brightness when the viewing angle ranges approximately from −75° to +75°. This indicates that within the ranges, the encapsulation structure 107 achieves better display quality.

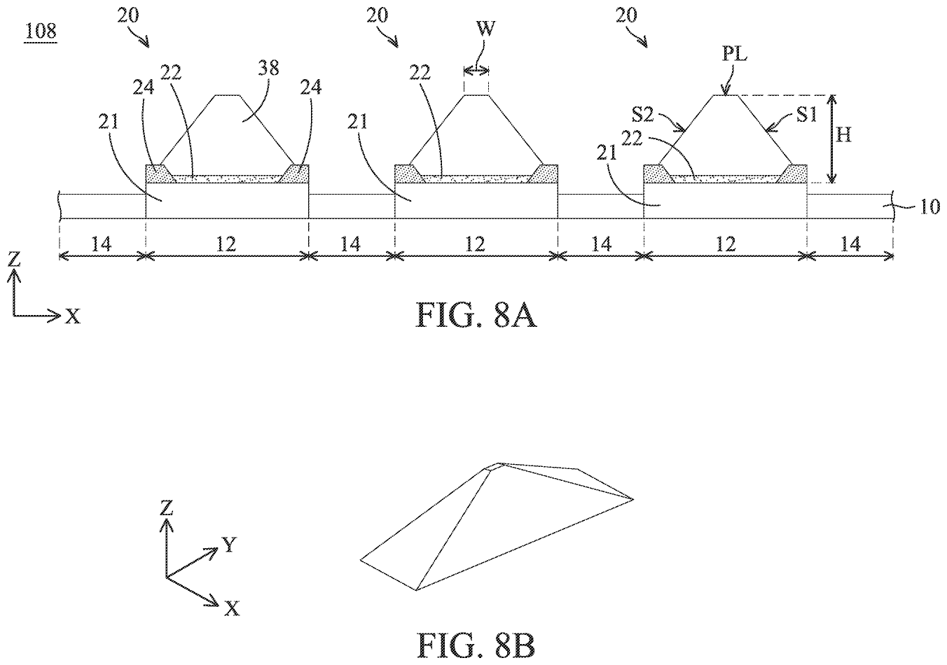

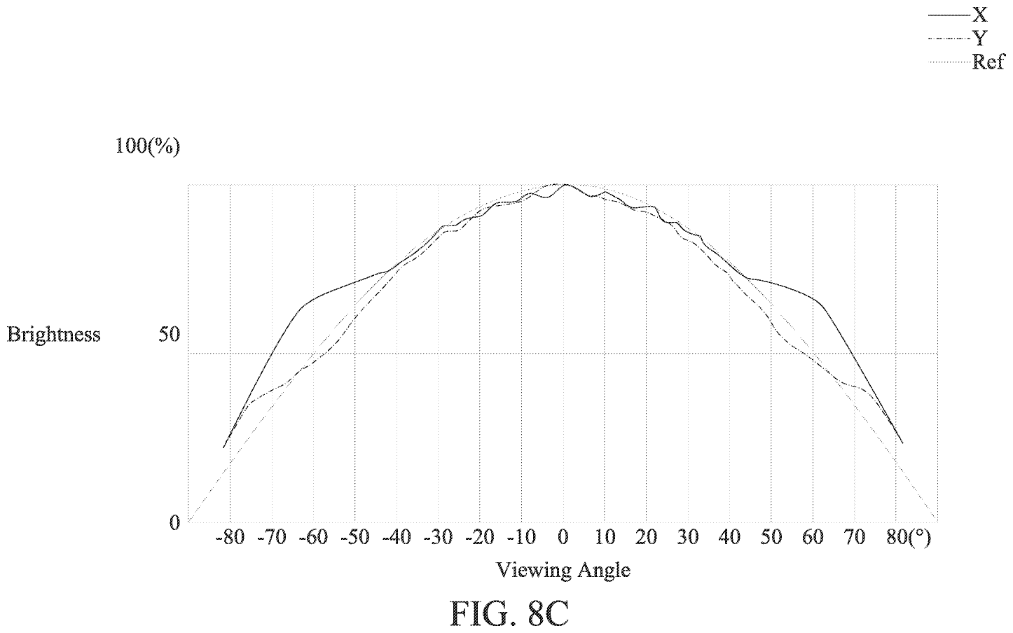

FIG. 8A is a partial cross-sectional view illustrating the encapsulation structure 108 according to an embodiment of the present disclosure. FIG. 8B is a three dimensional view illustrating the light-guiding structure 38 according to an embodiment. FIG. 8C is a simulation diagram showing the brightness of the light-guiding structure 38 observed from different positions in the encapsulation structure 108. Similarly, some components of the encapsulation structure 108 have been omitted in FIG. 8A for the sake of brevity. Although not shown in FIG. 8A, in other embodiments, the encapsulation structure 108 may also include a barrier layer 50 covering the light-guiding structure 38, which will not be further elaborated here.

As shown in FIG. 8A and FIG. 8B, in this embodiment, the light-guiding structure 38 is a convex structure, and in the cross-section shown in FIG. 8A, the light-guiding structure 38 includes two inclined surfaces S1 and S2. As shown in FIG. 8B, in this embodiment, the light-guiding structure 38 may be a quasi-rectangular pyramid with a flat portion PL on the top. The cross-section of the light-guiding structure 38 cut along the X-axis (i.e., the X-Z cross-section shown in FIG. 8A) includes two inclined surfaces, and the cross-section of the light-guiding structure 38 cut along the Y-axis (the unillustrated Y-Z cross-section) also includes two inclined surfaces.

In this embodiment, the light-guiding structure 38 has a refractive index of approximately 1.4, the maximum thickness H of the light-guiding structure 38 (see FIG. 8A) is about 14 μm, and the width W of the flat portion PL on the top of the light-guiding structure 38 (as seen in FIG. 8A) is about 4 μm. As shown in FIG. 8C, when the viewing angle ranges approximately from −40° to −75° or from +40° to +75°, the brightness of line segment X is higher compared to line segment Ref. That is, it has sufficient brightness when the viewing angle ranges approximately from −60° to +60°. This indicates that within the ranges, the encapsulation structure 108 achieves better display quality.

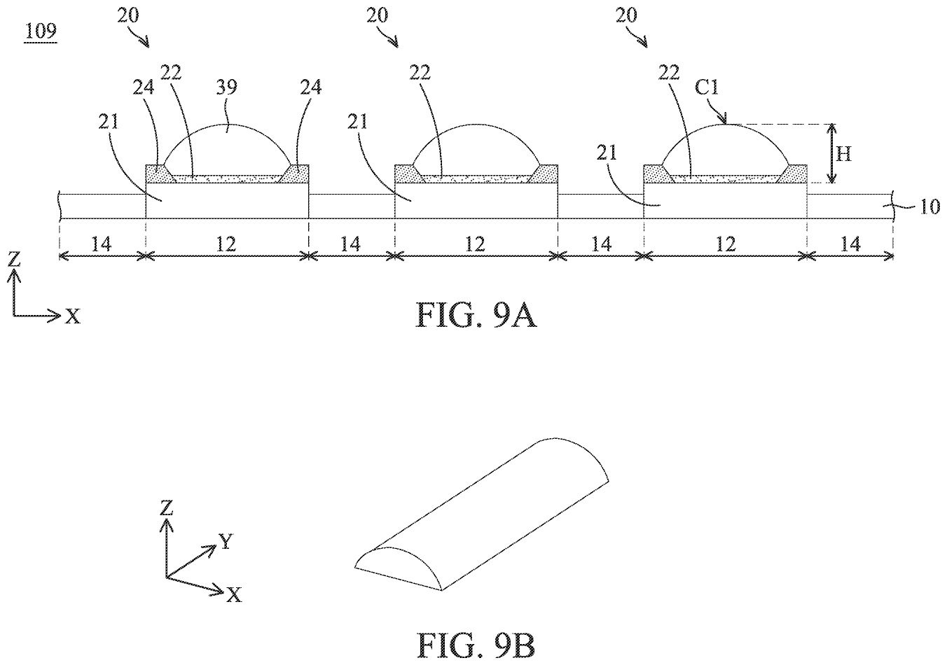

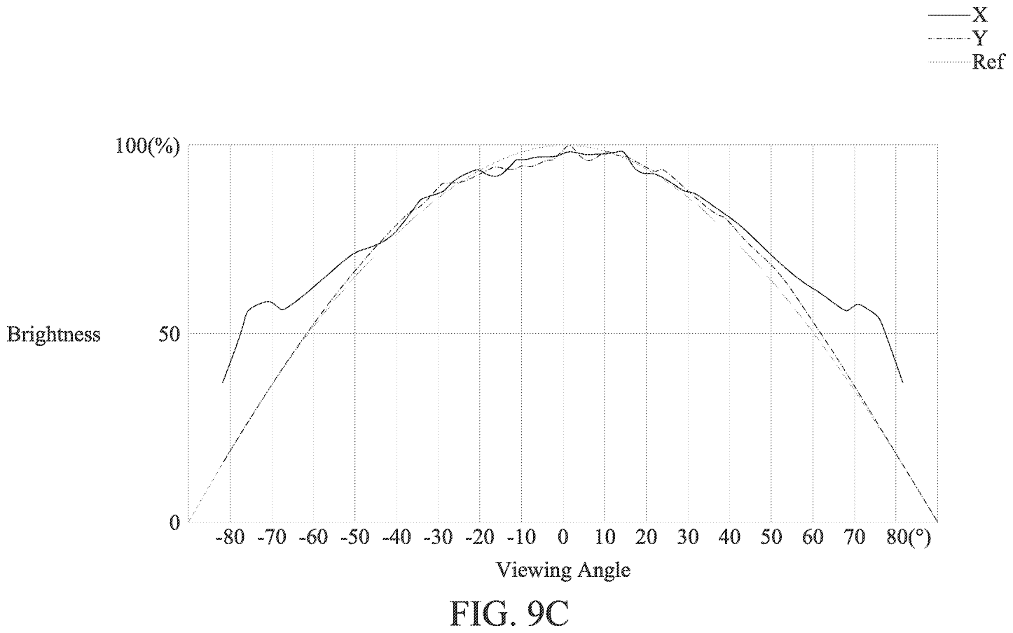

FIG. 9A is a partial cross-sectional view illustrating the encapsulation structure 109 according to an embodiment of the present disclosure. FIG. 9B is a three dimensional view illustrating the light-guiding structure 39 according to an embodiment. FIG. 9C is a simulation diagram showing the brightness of the light-guiding structure 39 observed from different positions in the encapsulation structure 109. Similarly, some components of the encapsulation structure 109 have been omitted in FIG. 9A for the sake of brevity. Although not shown in FIG. 9A, in other embodiments, the encapsulation structure 109 may also include a barrier layer 50 covering the light-guiding structure 39, which will not be further elaborated here.

As shown in FIG. 9A and FIG. 9B, in this embodiment, the light-guiding structure 39 is a convex structure, and in the cross-section shown in FIG. 9A, the light-guiding structure 39 includes one curved surface C1. As shown in FIG. 9B, the light-guiding structure 39 is part of a cylinder (e.g., a semi-cylinder). The cross-section of the light-guiding structure 39 cut along the X-axis (i.e., the X-Z cross-section shown in FIG. 9A) is arc-shaped, which includes one curved surface. The Y-Z cross-section shown in FIG. 9B may also be arc-shaped.

In this embodiment, the light-guiding structure 39 has a refractive index of approximately 1.4, the maximum thickness H of the light-guiding structure 39 (see FIG. 9A) is about 5 μm, and the radius of curvature of the light-guiding structure 39 is about 8 μm. As shown in FIG. 9C, when the viewing angle ranges approximately from −45° to −75° or from +45° to +75°, the brightness of line segment X is higher compared to line segment Ref. That is, it has sufficient brightness when the viewing angle ranges approximately from −75° to +75°. This indicates that within the ranges, the encapsulation structure 109 achieves better display quality.

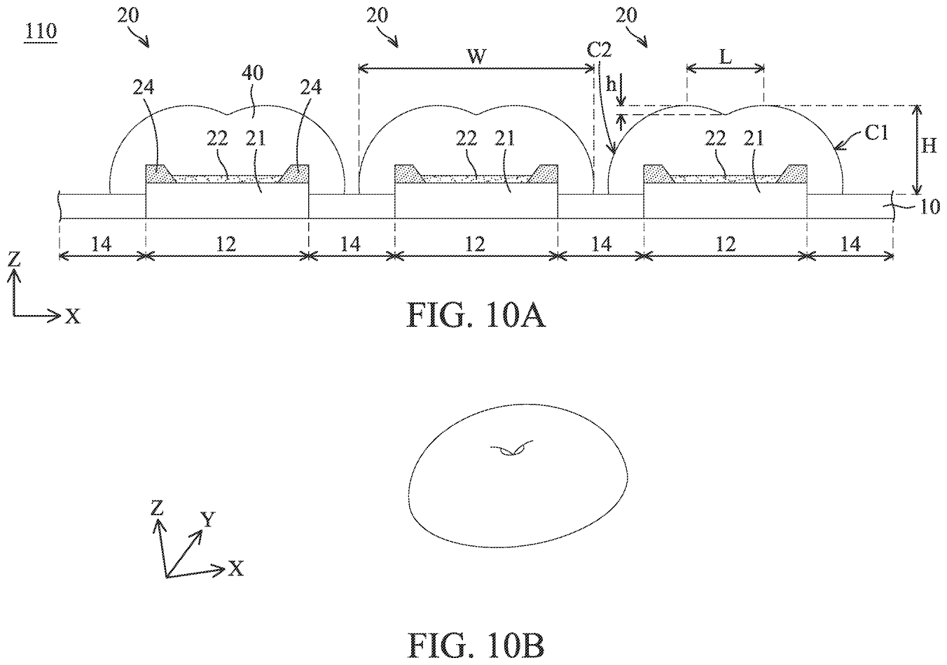

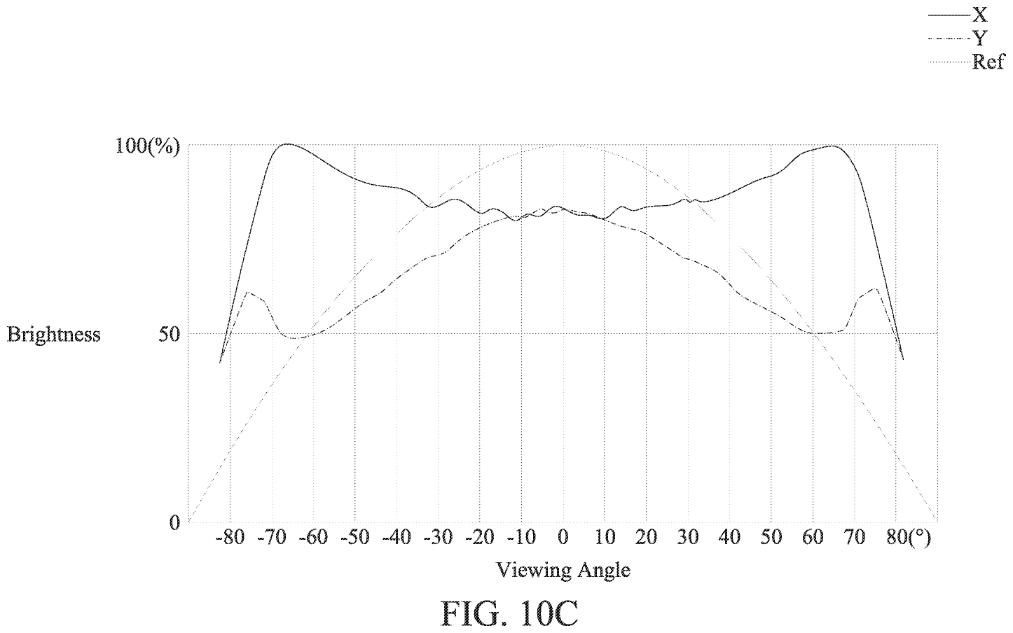

FIG. 10A is a partial cross-sectional view illustrating the encapsulation structure 110 according to an embodiment of the present disclosure. FIG. 10B is a three dimensional view illustrating the light-guiding structure 40 according to an embodiment. FIG. 10C is a simulation diagram showing the brightness of the light-guiding structure 40 observed from different positions in the encapsulation structure 110. Similarly, some components of the encapsulation structure 110 have been omitted in FIG. 10A for the sake of brevity. Although not shown in FIG. 10A, in other embodiments, the encapsulation structure 110 may also include a barrier layer 50 covering the light-guiding structure 40, which will not be further elaborated here.

As shown in FIG. 10A and FIG. 10B, in this embodiment, the light-guiding structure 40 is a convex structure, and in the cross-section shown in FIG. 10A, the light-guiding structure 40 includes two curved surfaces C1 and C2. As shown in FIG. 10B, in this embodiment, the light-guiding structure 40 may be donut-like. The cross-section of the light-guiding structure 40 cut along the X-axis (i.e., the X-Z cross-section shown in FIG. 10A) includes two curved surfaces, and the cross-section of the light-guiding structure 40 cut along the Y-axis (the unillustrated Y-Z cross-section) also includes two curved surfaces.

In this embodiment, the light-guiding structure 40 has a refractive index of approximately 1.4, the maximum thickness H of the light-guiding structure 40 (see FIG. 10A) is about 70 μm, the distance L between the two highest points at the top of the light-guiding structure 40 (see FIG. 10A) is about 30 μm, the overall width W of the light-guiding structure 40 (the same in both the X-direction and Y-direction) (see FIG. 10A) is about 70 μm, the distance h between the highest point and the recessed point of the light-guiding structure 40 (see FIG. 10A) is about 6.8 μm, and the radius of curvature of the two curved surfaces is about 20 μm. As shown in FIG. 10C, when the viewing angle ranges approximately from −35° to −80° or from +35° to +80°, the brightness of line segment X is higher compared to line segment Ref. That is, it has sufficient brightness when the viewing angle ranges approximately from −35° to −80° and from +35° to +80°. This indicates that within the ranges, the encapsulation structure 110 achieves better display quality.

The light-guiding structures in the present disclosure are not limited to the light-guiding structures 31-40 described in the aforementioned embodiments. In the embodiments of the present disclosure, the light-guiding structure may include a convex structure or a concave structure (or a combination thereof), where the convex structure in a cross-section has at least one curved surface, at least two inclined surfaces, or a combination of at least one curved surface and one inclined surface, and the concave structure in a cross-section has at least one curved surface or at least two inclined surfaces.

The light-guiding structure may be configured with light-emitting areas of different sizes and shapes. When the light-guiding structure includes a convex structure, it may have a light-converging effect, and when the light-guiding structure includes a concave structure, it may have a light-diffusing effect. For example, the light-guiding structure may include a hemisphere, a diamond shape, a tent-like shape, a cylinder, a cone, a cube, a tetrahedron, a pentahedron, or any other polyhedral shape, but the present disclosure is not limited thereto. By forming the light-guiding structure into a specific shape, the encapsulation structure according to the embodiments of the present disclosure may be applied to fixed curved surfaces with good light uniformity, achieving excellent display quality.

In some embodiments, a photoresist coating process may be performed first, where specific (shaped) light-guiding structures are layered (e.g., using software to output multiple cross-sectional image files) and set for layered laser exposure using a maskless exposure machine. By adjusting parameters and etching out specific optical structures, light-guiding structures with specific shapes may be completed, but the production of light-guiding structures in these embodiments is not limited thereto.

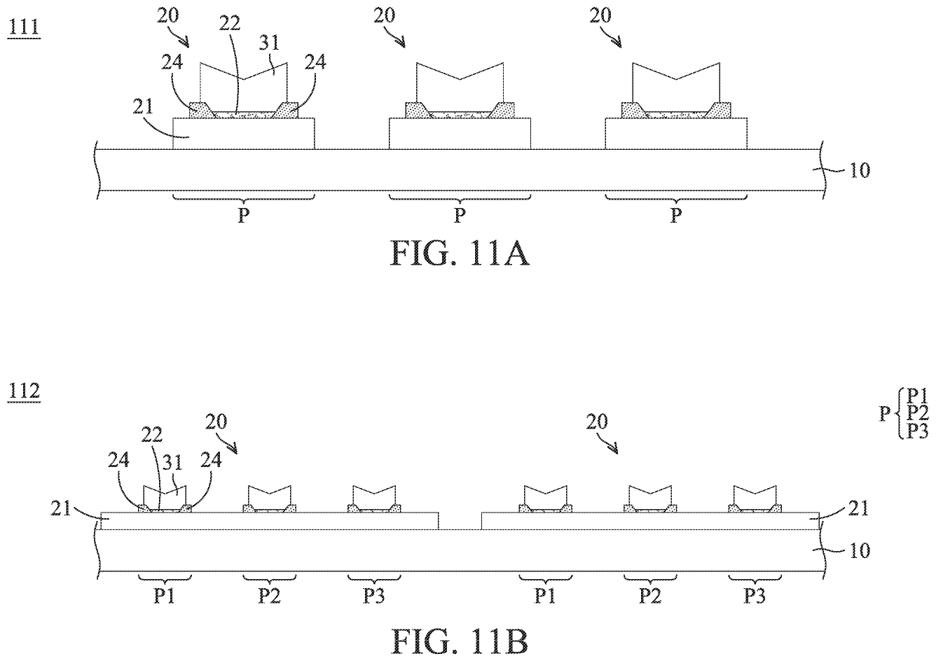

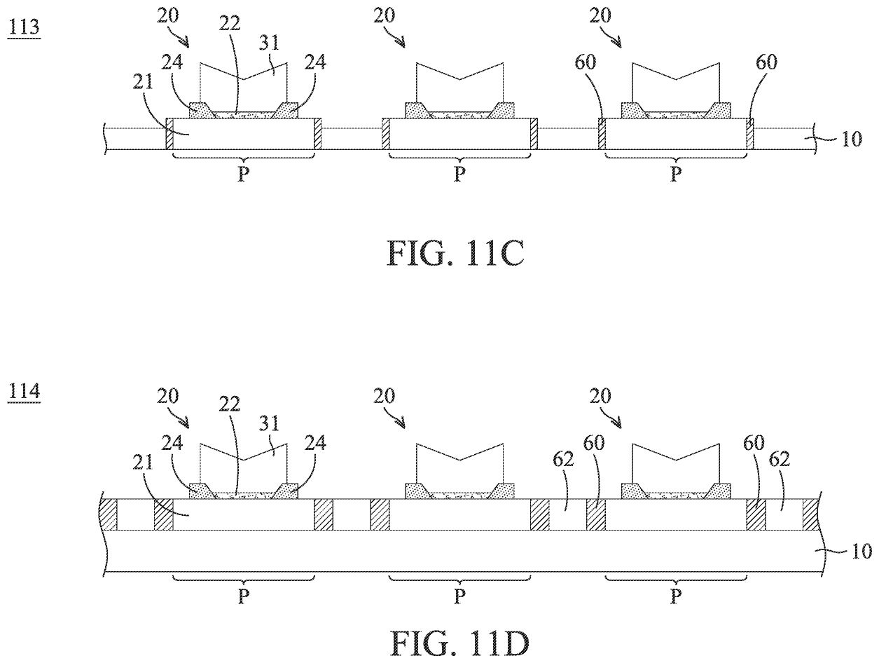

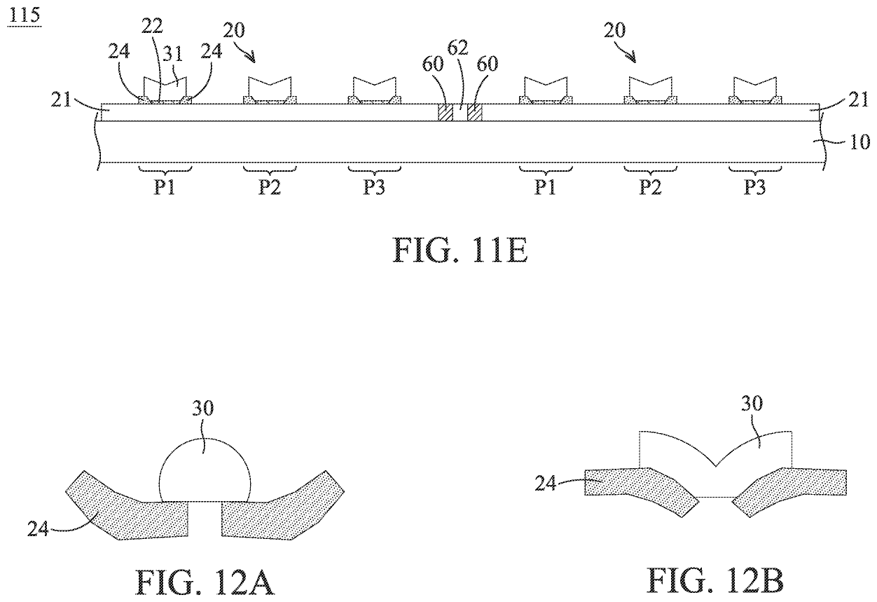

In the aforementioned embodiments, the electronic element 20 may be embedded within the flexible substrate 10, but the present disclosure is not limited thereto. In some other embodiments, the electronic element 20 may be disposed on the flexible substrate 10. FIG. 11A to FIG. 11E are partial cross-sectional views illustrating encapsulation structures 111, 112, 113, 114, and 115 according to other embodiments of the present disclosure. Similarly, some components of the encapsulation structures 111, 112, 113, 114, and 115 have been omitted in FIG. 11A to FIG. 11E for the sake of brevity.

As shown in FIG. 11A, in this embodiment, the electronic element 20 of the encapsulation structure 111 is disposed on the flexible substrate 10, and each electronic element 20 corresponds to one pixel P. As shown in FIG. 11B, in this embodiment, the electronic element 20 of the encapsulation structure 112 is disposed on the flexible substrate 10, each electronic element 20 corresponds to one pixel P, and the pixel P may include at least three sub-pixels P1, P2, and P3 (e.g., red light, green light, or blue light).

As shown in FIG. 11C, in this embodiment, the electronic element 20 of the encapsulation structure 113 is embedded within the flexible substrate 10, and the encapsulation structure 113 further includes multiple buffer structures 60 that surround the electronic elements 20 (e.g., surround the control substrate 21). For example, the buffer structure 60 may include acrylic resin, epoxy resin, phenolic resin, or any similar material. Alternatively, the buffer structure 60 may have a feedback sensing function, capable of sensing deformation of the flexible substrate 10 and making corresponding adjustments, but the present disclosure is not limited thereto.

As shown in FIG. 11D, in this embodiment, the electronic element 20 of the encapsulation structure 114 is disposed on the flexible substrate 10, and each electronic element 20 corresponds to one pixel P. The encapsulation structure 114 further includes multiple buffer structures 60 and multiple elastic bodies 62, the buffer structures 60 surround electronic elements 20 (for example, surround control substrate 21), and the elastic bodies 62 are disposed between the buffer structures 62.

As shown in FIG. 11E, in this embodiment, the electronic element 20 of the encapsulation structure 115 is disposed on the flexible substrate 10, each electronic element 20 corresponds to one pixel P, and the pixel P may include at least three sub-pixels P1, P2, and P3 (for example, red light, green light, or blue light). The encapsulation structure 115 further includes multiple buffer structures 60 and multiple elastic bodies 62, the buffer structures 60 surround electronic elements 20 (for example, surround control substrate 21), and the elastic bodies 62 are disposed between the buffer structures 62.

In the embodiments of the present disclosure (including the aforementioned embodiments), the light-guiding structure may be a fixed structure or a deformable structure. In the embodiments where the light-guiding structure is deformable, the encapsulation body may serve as a shape-adjusting pad. The shape-adjusting pad is in direct or indirect contact with the deformable light-guiding structure to change the shape of the deformable light-guiding structure.

FIG. 12A and FIG. 12B are partial cross-sectional views illustrating changing the shape of the light-guiding structure 30 through the encapsulation body 24 (shape-adjusting pad) according to an embodiment of the present disclosure. In some embodiments, the light-guiding structure 30 is a deformable bag of liquid or gel, and the light-guiding structure 30 is in direct contact with the corresponding encapsulation body 24 (shape-adjusting pad). As shown in FIG. 12A, the nearly spherical the light-guiding structure 30 may be deformed through the encapsulation body 24 (shape-adjusting pad) to become a concave structure as shown in FIG. 12B, but the present disclosure is not limited thereto.

For example, when the encapsulation body 24 serves as a shape-adjusting pad, the buffer structure 60 in the aforementioned embodiments (e.g., FIG. 11C to FIG. 11E) may have a feedback sensing function. The buffer structure 60 may sense the deformation of the flexible substrate 10 and then change the shape of the light-guiding structure 30 through the encapsulation body 24, thereby adjusting the light-guiding structure 30 to a shape suitable for the current situation (i.e., having good brightness and uniformity of light).

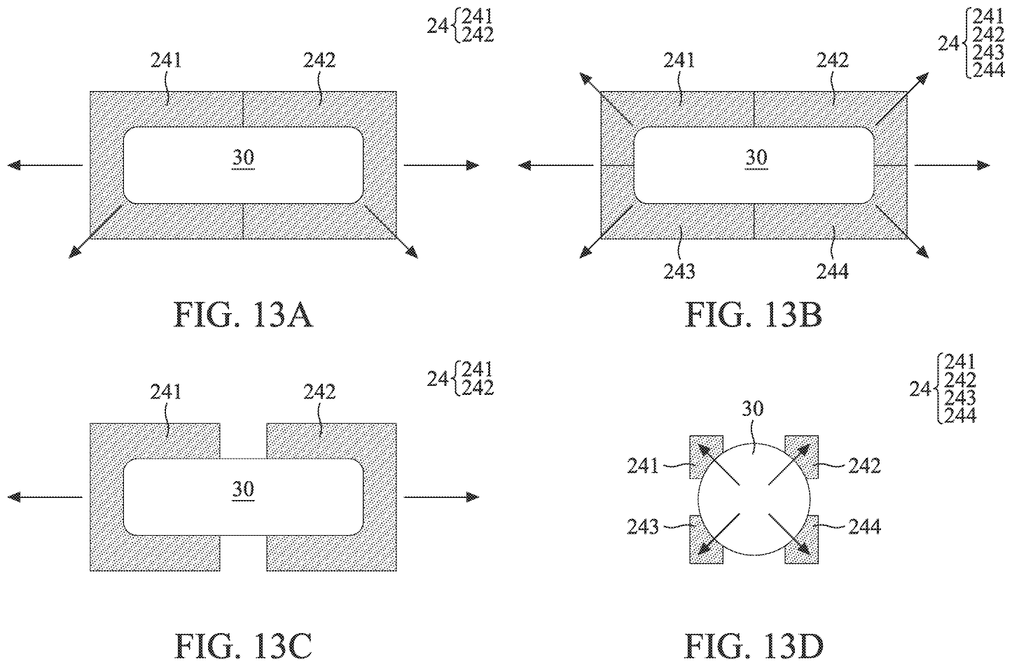

FIG. 13A to FIG. 13D are top views illustrating the encapsulation body 24 (shape-adjusting pad) and the light-guiding structure 30 according to other embodiments of the present disclosure. It should be noted that the real shape of the light-guiding structure 30 is not shown in FIG. 13A to FIG. 13D, only the relative relationship with the encapsulation body 24 is indicated.

As shown in FIG. 13A, in this embodiment, the encapsulation body 24 (shape-adjusting pad) may be divided into two sub-sections 241 and 242. The sub-section 241 and the sub-section 242 are connected to each other, and the light-guiding structure 30 is in the area between the sub-section 241 and the sub-section 242. The sub-section 241 and the sub-section 242 may be bent or twisted up and down along the arrow direction in FIG. 13A to produce deformation, thereby changing the shape of the light-guiding structure 30, but the present disclosure is not limited thereto.

As depicted in FIG. 13B, in this embodiment, the encapsulation body 24 (shape-adjusting pad) may be divided into four sub-sections 241, 242, 243, and 244. Adjacent two sub-sections 241 and 242, sub-sections 243 and 244, sub-sections 241 and 243, or sub-sections 242 and 244 may be folded over each other to produce a three-dimensional deformation (e.g., folding up and down, displacement, or twisting), thereby changing the shape of the light-guiding structure 30, but the present disclosure is not limited thereto.

As shown in FIG. 13C, in this embodiment, the encapsulation body 24 (shape-adjusting pad) may be divided into two sub-sections 241 and 242. The sub-section 241 and the sub-section 242 are connected to each other, and the light-guiding structure 30 is in the area between the sub-section 241 and the sub-section 242. The sub-section 241 and the sub-section 242 may move outward or fold vertically up and down (e.g., displacement or twisting) along the arrow direction in FIG. 13C to produce a three-dimensional deformation, thereby changing the shape of the light-guiding structure 30, but the present disclosure is not limited thereto.

As shown in FIG. 13D, in this embodiment, the encapsulation body 24 (shape-adjusting pad) may be divided into four sub-sections 241, 242, 243, and 244. The sub-sections 241, 242, 243, and 244 are separated from each other, and the light-guiding structure 30 is in the area between the sub-sections 241, 242, 243, and 244. The sub-sections 241, 242, 243, and 244 may move outward or fold vertically up and down (e.g., displacement or twisting) along the arrow direction in FIG. 13D to produce a three-dimensional deformation, thereby changing the shape of the light-guiding structure 30, but the present disclosure is not limited thereto.

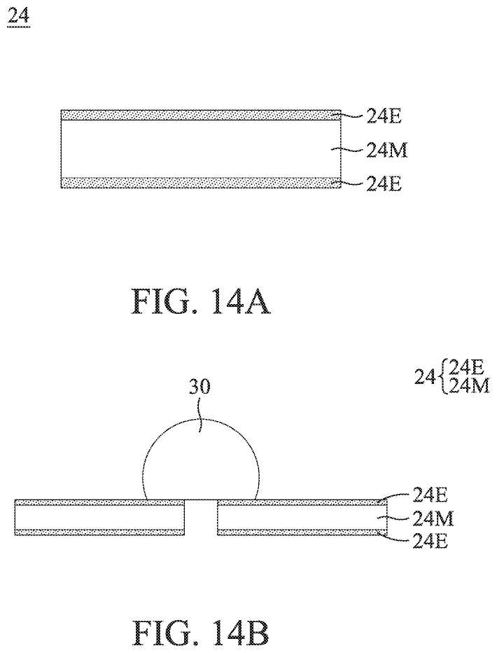

FIG. 14A is a partial cross-sectional schematic view illustrating the encapsulation body 24 (shape-adjusting pad) according to an embodiment of the present disclosure. FIG. 14B illustrates a partial cross-sectional schematic view of changing the shape of the light-guiding structure 30 through the encapsulation body 24 (shape-adjusting pad) according to an embodiment of the present disclosure.

In some embodiments, the encapsulation body 24 may include, for example, piezoelectric material. As shown in FIG. 14A, the encapsulation body 24 includes two electrodes 24E and a piezoelectric intermediate 24M between the electrodes 24E. For example, the piezoelectric intermediate 24M may include piezoelectric single crystals (e.g., SiO₂, LiTaO₃, LiNbO₃, BaTiO₃), piezoelectric polycrystals (e.g., piezoelectric ceramics, which may include SiO₂, LiTaO₃, LiNbO₃, BaTiO₃, PZT, ZnO, Pb(ZrTi)O₃), piezoelectric polymers, or piezoelectric composite materials. Commonly used piezoelectric polymers include polyvinylidene difluoride (PVDF), but the present disclosure is not limited thereto.

As shown in FIG. 14B, the encapsulation body 24 may change the shape of the light-guiding structure 30 by generating a clustering effect inside a gel or liquid through the electrophoresis principle or the principle of polarization caused by voltage or current, thereby improving the uniformity of light and increasing the viewing angle.

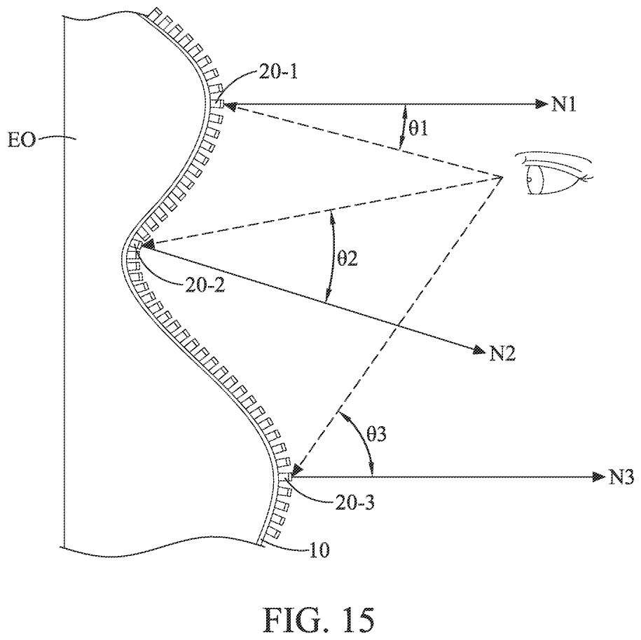

FIG. 15 is a schematic view of applying (e.g., attaching) the encapsulation structure of the present disclosure to an object EO with a curved surface (e.g., the A-pillar of a car) according to an embodiment of the present disclosure. As shown in FIG. 15, the included angle θ1 between the observer's eye and the normal line N1 of the electronic element 20-1 may be less than or equal to 30° (i.e., 01≤30°). The included angle θ2 between the observer's eye and the normal line N2 of the electronic element 20-2 may be greater than or equal to 30° and less than or equal to 60° (i.e., 30°≤θ2≤60°), and the included angle θ3 between the observer's eye and the normal line N3 of the electronic element 20-3 may be greater than or equal to 60° and less than or equal to 85° (i.e., 60°≤θ3≤85°). To the observer, the electronic element 20-1 and the electronic element 20-3 are, for example, located on the positive curved surface (i.e., convex surface) of the object EO, while electronic element 20-2 is, for example, located on the negative curved surface (i.e., concave surface) of the object EO.

In some embodiments, the electronic element 20-1 may be matched with the light-guiding structure 32 shown in FIG. 2B, the light-guiding structure 33 shown in FIG. 3B, the light-guiding structure 34 shown in FIG. 4B, the light-guiding structure 35 shown in FIG. 5B, the light-guiding structure 36 shown in FIG. 6B, the light-guiding structure 37 shown in FIG. 7B, the light-guiding structure 38 shown in FIG. 8B, or the light-guiding structure 39 shown in FIG. 9B, respectively, to achieve better brightness and uniformity of light, but the present disclosure is not limited thereto.

In some embodiments, the electronic element 20-2 may be matched with the light-guiding structure 31 shown in FIG. 1B, the light-guiding structure 32 shown in FIG. 2B, the light-guiding structure 33 shown in FIG. 3B, the light-guiding structure 34 shown in FIG. 4B, or the light-guiding structure 40 shown in FIG. 10B, respectively, to achieve better brightness and uniformity of light, but the present disclosure is not limited thereto.

In some embodiments, the electronic element 20-3 may be matched with the light-guiding structure 35 shown in FIG. 5B, the light-guiding structure 37 shown in FIG. 7B, or the light-guiding structure 40 shown in shown in FIG. 10B, respectively, to achieve better brightness and uniformity, but the present disclosure is not limited thereto.

In other words, depending on the different curved surfaces (i.e., different concave surfaces, convex surfaces, or different radii of curvature) of the object being attached, a selection of at least one type (inclined and/or curved) of multiple light-guiding structures may be arranged or configured in combination based on the included angle between the observer's eye and the normal line of the electronic elements. That is, within the same display, there may be more than one shape of light-guiding structures to achieve better brightness and uniformity of light.

In the encapsulation structure that includes the light-guiding structure of the present disclosure, the light-emitting range of the electronic element is within about ±85° of an angle based on the normal line of the electronic element. That is, when the included angle between the observer's eyes and the electronic element is within the aforementioned range, good viewing quality may be achieved. Compared to traditional encapsulation structures without light-guiding structures, where the light-emitting range of the electronic element is within about ±10° of an angle based on the normal line of the electronic element, the light-guiding structures according to the embodiments of the present disclosure may effectively expand the light-emitting range of electronic element.

The encapsulation structure according to the embodiments of the present disclosure includes light-guiding structures, which themselves may have specific shapes, or may be changed into specific shapes through shape-adjusting pads. This allows the encapsulation structure according to the embodiments of the present disclosure to be applied to fixed curved surfaces or flexible electronic devices, possessing good light uniformity to achieve excellent display quality.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims and its equivalent scope. In addition, although some embodiments of the present disclosure are disclosed above, they are not intended to limit the scope of the present disclosure.

What is claimed is:

1. An encapsulation structure, comprising:
a flexible substrate having an element area and a non-element area;
a plurality of electronic elements disposed in the element area; and
a plurality of light-guiding structures disposed on the plurality of electronic elements, wherein each of the plurality of light-guiding structures comprises a convex structure or a concave structure,
wherein the convex structure has at least two curved surfaces, at least two inclined surfaces, or a combination of at least one curved surface and one inclined surface in a cross-section; and
wherein the concave structure has at least one curved surface or at least two inclined surfaces in a cross-section.

2. The encapsulation structure as claimed in claim 1, wherein at least one of the plurality of light-guiding structures comprises a groove that is formed by two inclined surfaces or two curved surfaces.

3. The encapsulation structure as claimed in claim 1, wherein at least one of the plurality of light-guiding structures comprises two inclined surfaces or two curved surfaces in two mutually perpendicular cross-sections.

4. The encapsulation structure as claimed in claim 1, wherein the plurality of light-guiding structures comprises a triangular prism, a quadrangular prism, a quadrangular pyramid, or a combination thereof.

5. The encapsulation structure as claimed in claim 1, wherein at least one of the plurality of light-guiding structures comprises trapezoidal or arc-shaped in a cross-section.

6. The encapsulation structure as claimed in claim 1, further comprising:
a barrier layer covering the plurality of light-guiding structures.

7. The encapsulation structure as claimed in claim 1, wherein each of the plurality of light-guiding structures corresponds to a pixel structure or a sub-pixel structure among the plurality of electronic elements.

8. The encapsulation structure as claimed in claim 1, wherein the plurality of electronic elements are embedded within the flexible substrate.

9. The encapsulation structure as claimed in claim 1, wherein the plurality of electronic elements are disposed on the flexible substrate.

10. The encapsulation structure as claimed in claim 1, further comprising:
a plurality of buffer structures surrounding the plurality of electronic elements.

11. The encapsulation structure as claimed in claim 10, further comprising:
a plurality of elastic bodies disposed between at least two of the plurality of buffer structures.

12. The encapsulation structure as claimed in claim 1, wherein each of the plurality of electronic elements comprises:
a control substrate connected to the flexible substrate; and
a light-emitting structure disposed on the control substrate.

13. The encapsulation structure as claimed in claim 12, further comprising:
a plurality of encapsulation bodies surrounding the plurality of light-emitting structures.

14. The encapsulation structure as claimed in claim 13, wherein the plurality of encapsulation bodies are in direct contact with corresponding ones of the plurality of light-guiding structures, and each of the plurality of encapsulation bodies is a shape-adjusting pad for adjusting a shape of a corresponding one of the plurality of light-guiding structures.

15. The encapsulation structure as claimed in claim 14, wherein at least one of the plurality of encapsulation bodies is divided into at least two sub-sections.

16. The encapsulation structure as claimed in claim 15, wherein the sub-sections are separated from each other.

17. The encapsulation structure as claimed in claim 14, wherein the plurality of encapsulation bodies comprise piezoelectric material.

18. The encapsulation structure as claimed in claim 14, wherein each of the plurality of light-guiding structures comprises a deformable bag of liquid or gel.

19. The encapsulation structure as claimed in claim 1, wherein a light-emitting range of each of the plurality of electronic elements is within ±85° of an angle based on a normal line of each of the plurality of electronic elements.

20. An encapsulation structure, comprising:
a flexible substrate having an element area and a non-element area;
an electronic element disposed in the element area;
a deformable light-guiding structure disposed on the electronic element; and
a shape-adjusting pad in direct or in indirect contact with the deformable light-guiding structure for changing a shape of the deformable light-guiding structure.
